(19) United States
(12) Patent Application Publication
(10) Pub. No.: US 2025/0372918 A1
(43) Pub. Date: Dec. 4, 2025

(54) STRAIN RELIEF MECHANISM FOR POWER CORD IN RESTRICTED CHASSIS SPACE

(71) Applicant: SCHNEIDER ELECTRIC IT CORPORATION, Foxboro, MA (US)

(72) Inventor: Yuchun Jiang, Saint Peters, MO (US)

(21) Appl. No.: 19/218,798

(22) Filed: May 27, 2025

Related U.S. Application Data
(60) Provisional application No. 63/652,230, filed on May 28, 2024.

(51) Int. Cl. H01R 13/56; H01R 13/58; H05K 7/14

(52) U.S. Cl. CPC H01R 13/562; H01R 13/5825; H05K 7/1491; H05K 7/1492

(57) ABSTRACT

A cable clamp assembly includes a chassis, a first clamp portion coupled to the chassis, a cover configured to releasably enclose the chassis, and a second clamp portion configured to be positioned between the first clamp portion and the cover. The second clamp portion includes a jack screw configured to transfer a force from the cover to the second clamp portion and a cable disposed between the first clamp portion and the second clamp portion.

### CROSS-REFERENCE TO RELATED APPLICATION

This application claims priority to U.S. Provisional Patent Application No. 63/652,230, filed May 28, 2024, titled STRAIN RELIEF MECHANISM FOR POWER CORD IN RESTRICTED CHASSIS SPACE, which is incorporated by reference in its entirety for all purposes.

### BACKGROUND OF DISCLOSURE

### 1. Field of Disclosure

Aspects and embodiments of the present invention are directed generally to electronic equipment, and more specifically, to a power distribution unit including a chassis having a plurality of outlets provided along a length of the chassis and a power cord secured to the chassis by a strain relief mechanism, sometimes referred to herein as a cable clamp assembly.

### 2. Discussion of Related Art

In response to the increasing demands of information-based economies, information technology networks continue to proliferate across the globe. One manifestation of this growth is the centralized network data center. A centralized network data center typically consists of various information technology equipment, co-located in a structure that provides network connectivity, electrical power, and cooling capacity. Often the equipment is housed in specialized enclosures termed “racks” which integrate these connectivity, power and cooling elements.

Equipment racks may include power distribution and wire management systems coupled to the racks to supply power and communication lines to the equipment in the racks. A type of power distribution system often used in electronic equipment racks, referred to as a rack power distribution unit or rPDU, includes multiple electrical outlets of the same or different specification for supplying power to equipment in a rack. One or more rPDUs may be mounted, for example, on one or both sides of a front and/or a rear of an equipment rack. Such rPDUs may include elongated power strips having multiple outlets or receptacles configured to receive various types of plugs. It is desired that the plugs are securely received within their respective outlets and adequately grounded.

A typical rack power distribution unit (rPDU), such as the rPDU, generally indicated at 10, shown in FIG. 1, includes an rPDU chassis 12 that houses outlets, breakers, printed circuit boards (PCBs), wires and other components, and a power cord 14 connected to the chassis and configured to provide power to the components housed within the chassis. The power cord 14 is installed on the rPDU chassis 12 with a strain relief to comply with required pulling and twisting forces. rPDUs used in high power density applications require large diameter input power cords. In an effort to reduce the cross-sectional size of the rPDU, there are instances in which the rPDU chassis 12 is only slightly wider than a required diameter of the power cord 14, thereby making it difficult to firmly secure the power cord to the rPDU chassis.

FIGS. 2 and 3 illustrate presently available strain relief mechanisms for rPDU chassis. As shown, the power cord 14 is secured to the rPDU chassis 12 by a strain relief scaling nut 20 provided outside the rPDU chassis and a locking nut 22 provided within the rPDU chassis. The use of the strain relief scaling and locking nuts 20, 22 prevents the power cord 14 from being turned once it clears an edge of the rPDU chassis 12. FIG. 4 illustrates a custom strain relief that uses two half clamps 40, 42 with long screws 44 that extend between the clamps. The known designs to secure the power cord 14 to the chassis 12 operate when a diameter of the power cord is meaningfully smaller than a width or cross-section of an rPDU chassis.

It should be appreciated that at least one purpose of providing a strain relief mechanism is to apply substantial clutching of the cable within the chassis of the rPDU to prevent the cable from being pulled out of the chassis thus leading to damage and/or hazardous electrical conditions. At the same time, the strain relief mechanism should not be secured too tight to the cable to cause damage to the cable. The assembly of the rPDU on a bench by personnel is complicated by the fact that the chassis of the rPDU is rather narrow on two sides of the chassis. Thus, it is difficult to apply pressure on the cable to maintain the cable in place with respect to the chassis. The action of inserting the cable through the strain relief mechanism, rotating the cable to align the wires of the cable to landing points (terminal block positions), and torquing a strain relief nut are all motions that challenge the case of assembly.

### SUMMARY OF DISCLOSURE

A strain relief mechanism described herein is for rack power distribution units (rPDUs) in which the diameter of a power cord is only slightly smaller than a width of an rPDU chassis. Presently available strain relief designs and other custom solutions are not suitable for situations in which the diameter of the power cord is slightly smaller than the width of the rPDU chassis. The strain relief mechanism of the present disclosure includes two identical clamp halves and several flat head screws to secure the cord to the chassis. In another embodiment, the two clamp halves may vary from one another. The strain relief mechanism of embodiments of the present disclosure is designed to operate within an rPDU chassis having restricted space. The strain relief mechanism further reduces physical length of the rPDU when strain relief is considered. One aspect of the present disclosure is directed to a cable clamp assembly comprising a chassis, a first clamp portion coupled to the chassis, a cover configured to releasably enclose the chassis, and a second clamp portion configured to be positioned between the first clamp portion and the cover. The second clamp portion includes a jack screw configured to transfer a force from the cover to the second clamp portion and a cable disposed between the first clamp portion and the second clamp portion.

Embodiments of the cable claim assembly may include configuring the chassis with a bottom wall and two side walls extending from lateral edges of the bottom wall. The cover may be configured to engage the side walls to enclose the chassis. The first clamp portion may be positioned on the bottom wall at an end of the bottom wall and the second clamp portion may be positioned on the cover at an end of the cover. The cover may be secured at least one side wall of the chassis by at least one screw fastener. The cover may include an opening formed therein over the jack screw, with the jack screw including a head portion having a diameter larger than a diameter of the opening. The diameter of the opening may be sized to receive a tool therein to rotate the jack screw. The jack screw further may include a threaded end portion, with the threaded end portion of the jack screw being configured to be threadably received within a threaded opening formed in the upper clamp portion. Each of the first clamp portion and the second clamp portion may include at least one groove formed therein. The chassis may include an end flange configured to engage the first clamp portion to prevent axial movement of the first clamp portion and the cable from the chassis. The chassis may include a first retention member configured to releasably engage a second retention member of the second clamp portion to temporarily secure the second clamp portion in place when assembling the cable clamp assembly. The second clamp portion may include two jack screws that are spaced apart from one another, with the two jack screws being configured to transfer a force from the cover to the second clamp portion and the cable disposed between the first clamp portion and the second clamp portion. The first clamp portion and at least one screw fastener may be configured to secure the first clamp portion to the chassis.

Another aspect of the present disclosure is directed to a method of assembling a cable clamp assembly. In one embodiment, the method comprises: positioning a first clamp portion and a cable in a chassis; positioning a second clamp portion over the cable and on the first clamp portion; positioning a cover on the chassis to enclose the first clamp portion and the second clamp portion; securing the cover to the chassis; and rotating a jack screw configured to transfer a force from the cover to the second clamp portion and a cable disposed between the first clamp portion and the second clamp portion to secure the cable in place.

Embodiments of the method further may include positioning the second clamp portion on the cable over the first clamp portion to retain the second clamp portion to the chassis. Retaining the second clamp portion to the chassis may be achieved by a first retention member of the chassis that is configured to releasably engage a second retention member of the second clamp portion to temporarily secure the second clamp portion in place. The first clamp portion may be positioned on the bottom wall at an end of the bottom wall and the second clamp portion may be positioned on the cover at an end of the cover. The method further may include securing the cover to the chassis by at least one screw fastener. The cover may include an opening formed therein over the jack screw, with the jack screw including a head portion having a diameter larger than a diameter of the opening. The diameter of the opening may be sized to receive a tool therein to rotate the jack screw. The jack screw further may include a threaded end portion, with the threaded end portion of the jack screw being configured to be threadably received within a threaded opening formed in the upper clamp portion. Each of the first clamp portion and the second clamp portion may include at least one groove formed therein. The method further may include preventing axial movement of the first clamp portion and the cable from the chassis. Preventing axial movement of the cable from the chassis may include an end flange on the chassis that is configured to engage the first clamp portion. Rotating the jack screw includes rotating two jack screws that are spaced apart from one another. The method further may include securing the first clamp portion to the chassis by at least one screw fastener.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a plan view of a rack power distribution unit (rPDU) having a power cord secured to a chassis by strain relief sealing and locking nuts;

FIG. 2 is an enlarged perspective view of a portion of the rPDU shown in FIG. 1 showing the strain relief sealing nut used to secure the power cord to the chassis;

FIG. 3 is another enlarged perspective view of a portion of the rPDU shown in FIG. 1 showing the strain relief locking nut used to secure the power cord to the chassis;

FIG. 4 is an enlarged perspective view of a portion of an rPDU showing a custom approach to securing the power cord to the chassis of the rPDU;

FIG. 5 is a perspective view of an rPDU including a cable clamp assembly of an embodiment of the present disclosure to secure a power cord to a chassis of the rPDU;

FIG. 6 is a top exploded perspective view of the rPDU and the cable clamp assembly shown in FIG. 5;

FIG. 7 is bottom exploded perspective view of the rPDU and the cable clamp assembly shown in FIG. 5;

FIGS. 8A and 8B illustrate a clamp portion of the cable clamp assembly;

FIG. 9 is a perspective view of a portion of a chassis of the rPDU having a retention member used to temporarily secure a clamp portion;

FIG. 9A is an enlarged view of the retention member shown in FIG. 9;

FIG. 10 is a perspective view of a portion of the chassis of the rPDU having an end flange to retain the clamp portion;

FIGS. 11-14 are perspective views showing a sequence of assembly of the cable clamp assembly with the rPDU;

FIG. 15A is a cross-sectional view of a portion of the rPDU showing a jack screw in a disengaged position from a cover of the cable clamp assembly; and

FIG. 15B is a cross-sectional view of a portion of the rPDU showing the jack screw in an engaged position from the cover of the cable clamp assembly.

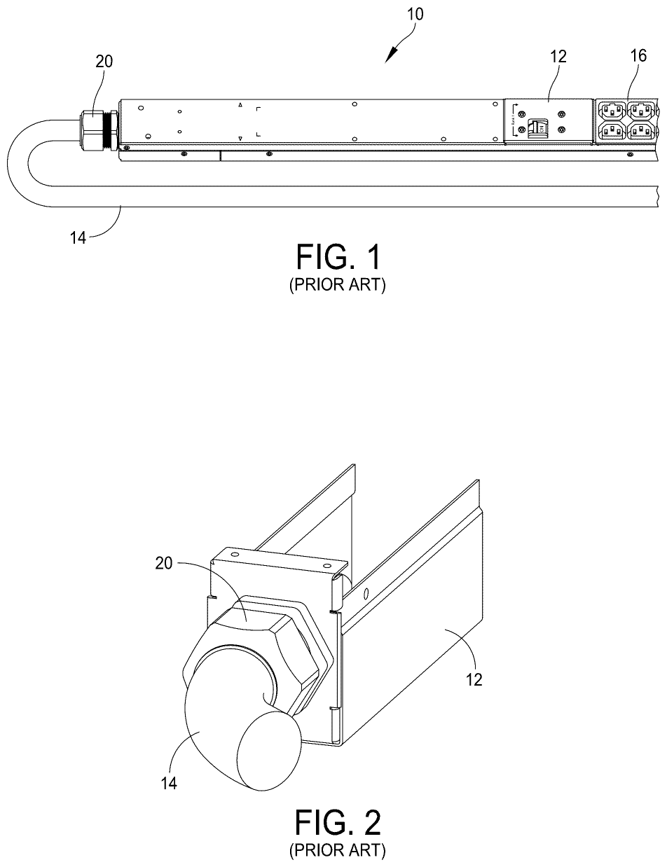

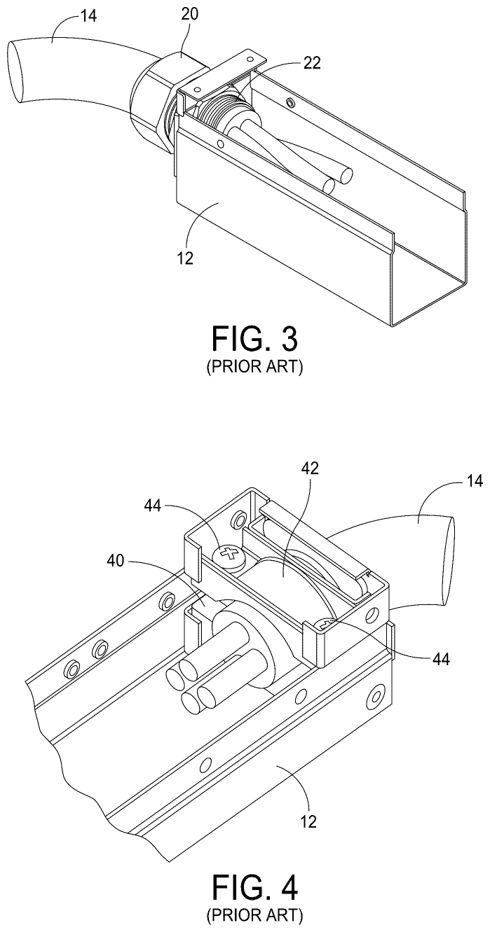

### DETAILED DESCRIPTION

Embodiments of the present disclosure are directed generally to a rack power distribution unit (rPDU) capable of providing power via outlets of the same or a different type arranged according to a desired configuration. The rPDU can be adapted to customer specifications identifying an arrangement of outlet types, and provides reductions in fabrication time, complexity, and cost.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples. For example, although the strain relief mechanism described herein is shown and described within an rPDU, the strain relief mechanism can be used in any situation in which a power cord is secured to a structure housing electronic components. For example, the strain relief mechanism can be used within uninterruptible power supplies (UPSs), power modules and other electronic devices. In other examples, the strain relief mechanism can be used for everyday appliances requiring power cords, e.g., kitchen appliances, household appliances, and the like.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated references is supplementary to that of this document; for irreconcilable inconsistencies, the term usage in this document controls.

An exemplary electronic equipment rack (also referred to herein simply as a “rack”) includes several enclosures that are configured to support power and/or network connections for other equipment mounted in the rack. As mentioned above, uninterruptible power supplies or UPSs may be installed as rack mounted devices to increase the power supply redundancy of the rack. The rack further may include computing or network technology equipment, for example, one or more data storage devices, a server, a patch panel, a keyboard tray, a cable organizer, and/or a monitor or other user interface, which may provide for an operator to communicate with the equipment in the rack. The rack further may be configured in any manner desired by the end user. A rack power distribution unit (rPDU) may be mounted internally within the rack in which the rPDU may be vertically mounted or may be horizontally mounted in the rack along with the other equipment in the rack. The rPDU may receive power from the UPSs in the rack, or directly from an AC utility supply, and may include power outlets to which power cords from the various other equipment in the rack may be electrically connected.

Referring back to FIG. 1, one example of the rPDU is illustrated. As described above, the rPDU 10 includes the elongated rectangular chassis 12 having the power cord 14 provided on an end of the chassis and at least one outlet bank, indicated at 16, provided on the front side of the chassis. The outlet bank 16 can be configured with a desired number of outlets, sometimes referred to herein as sockets. With embodiments of the present disclosure, the outlet bank 16 includes outlets that can serve a variety of outlet types. Although one outlet back 16 is shown, the chassis 12 of the rPDU 10 may be configured with any number of outlet backs depending on a length of the chassis.

In normal operation, the rPDU 10 is configured to receive power via the power cord 14, which is connected, for example, to an AC mains power supply or to a UPS, such as the UPS provided in the rack. The power received via the power cord 14 is distributed to each outlet of the outlet bank 16 to provide power to devices connected thereto. In some embodiments, the power bank 16 may include a dedicated circuit breaker to protect equipment connected to the power bank. The rPDU 10 further may include a user interface to control the operation of the rPDU and to provide an operator with useful information about the operation parameters of the rPDU.

In some embodiments, a cable clamp assembly includes an rPDU chassis, a first/bottom clamp portion coupled to the rPDU chassis, a cover configured to releasably enclose the rPDU chassis, and a second/top clamp portion disposed between the bottom clamp portion and the cover. The top clamp portion includes at least one jack screw that is configured to transfer a force from the cover to the top clamp portion and a cable disposed between the two clamp portions.

In some embodiments, the clamp portions of the cable clamp assembly grip the power cord when two jack screws are turned counterclockwise so that the upper clamp portion is pushed towards the lower clamp portion until they engage each other.

In some embodiments, retention features associated with the cable clamp assembly and retention features associated with side walls of the rPDU chassis may enable the clamp portion to temporarily secure the power cord in place during rPDU assembly.

In some embodiments, the cable clamp assembly includes a vertical step cut on the clamp portions to prevent the clamp portions from sliding inward within the rPDU chassis. The cover can also be configured to prevent the power cord from sliding inward within the rPDU chassis.

In some embodiments, each of the rPDU chassis and the cover may include an end flange to close a gap between the bottom clamp portion of the chassis and top clamp portion of the cover. The end flanges also prevent the clamp portions from sliding outward from the rPDU chassis.

In some embodiments, the two clamp portions of the cable clamp assembly may be identical to one another, or may be constructed differently from one another.

In some embodiments, components of cable clamp assembly may include, without limitation, a power cord, an rPDU chassis, a first or lower clamp portion, a cover, a second or upper clamp portion, one or more jack screws, several mounting screws, several chassis mounting screws, an end flange associated with the chassis, an end flange associated with the cover, grooves formed in the lower clamp portion, grooves formed in the upper clamp portion, retention features associated with the clamp portions, retention features associated with the rPDU chassis, threaded openings formed in lower clamp, and threaded openings formed in upper clamp.

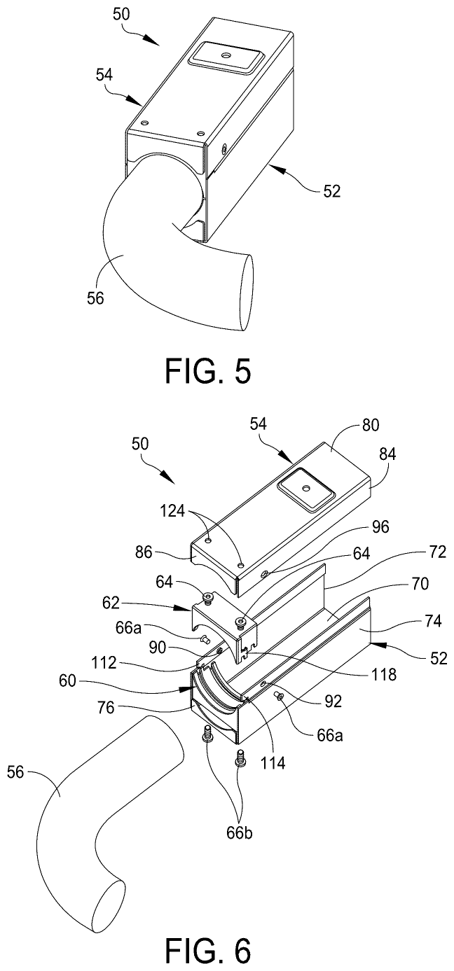

Referring to the drawings, and more particular to FIG. 5, a portion of an rPDU is generally indicated at 50. Other than the manner in which a power cord is secured to a chassis, the rPDU 50 is similar to rPDU 10 described above. As shown, the rPDU 50 includes a chassis, generally indicated at 52, which forms a portion of the rPDU and is configured to house the operational components of the rPDU, and a cover, generally indicated at 54, which is configured to enclose the chassis. The rPDU 50 further includes a power cord 56 provided on an end of the chassis 52. As with the rPDU 10 shown in FIG. 1, the chassis 52 of the rPDU 50 includes one or more outlet banks (not shown) that extend through the cover 54 of the rPDU. Each outlet bank can be configured with a desired number of outlets. As with the rPDU 10 shown in FIG. 1, in normal operation, the rPDU 50 is configured to receive power via the power cord 56, which is connected, for example, to an AC mains power supply or to a UPS, such as the UPS provided in the rack. The power received via the power cord 56 is distributed to each outlet of outlet banks to provide power to devices connected thereto. In some embodiments, each power bank may include a dedicated circuit breaker to protect equipment connected to the power bank. The rPDU 50 further may include a user interface to control the operation of the rPDU and to provide an operator useful information about the operation parameters of the rPDU.

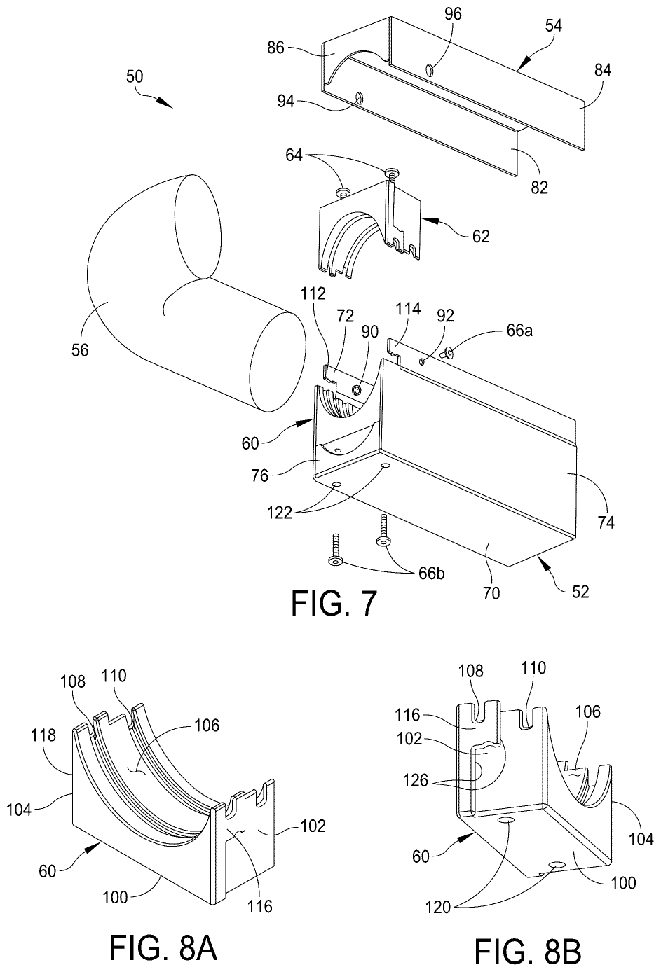

Referring to FIGS. 6 and 7, the chassis 52 and the cover 54 are shown apart from one another. As noted above, the lengths of the chassis 52 and the cover 54 are cut off for illustration purposes. As shown, the rPDU 50 includes a strain relief mechanism, sometimes referred to as a cable clamp assembly, having a first, lower clamp portion, generally indicated at 60, and a second, upper clamp portion, generally indicated at 62. The lower clamp portion 60 is positioned to be vertically oriented within the chassis 52 near an end of the chassis. The upper clamp portion 62 is similarly positioned to be vertically oriented within the cover 54 near an end of the cover and above the lower clamp portion 60. In the shown embodiment, each of the lower clamp portion 60 and the upper clamp portion 62 are U-shaped in construction, each having a semi-circular shape to receive the power cord 56 therein. The cable clamp assembly further includes two jack screws, each indicated at 64, to engage the cover 54 and the upper clamp portion 62, two chassis mounting screws, each indicated at 66a, to secure the cover 54 to the chassis 52, and two mounting screws, each indicated at 66b, to secure the lower clamp portion 60 within the chassis. When assembled, an end of the power cord 56 extends within the rPDU 50 between the chassis 52 and the cover 54.

The chassis 52 includes a bottom wall 70 and two side walls 72, 74 that extend from lateral edges of the bottom wall. As shown, the upper edges of the side walls 72, 74 each include a step formed along the edge of the side wall. The chassis 52 further includes an end flange 76 to partially enclose an end of the chassis. The end flange 76 is secured to the ends of the bottom wall 70 and the side walls 72, 74 of the chassis 52. Similarly, the cover 54 includes a top wall 80 and two side walls 82, 84 that extend from lateral edges of the top wall. The lower edges of the side walls 82, 84 also each include a step formed along the edge of the side wall to mate with the stepped edge of the side walls 72, 74 of the chassis 52. The result is that the side walls 82, 84 of the cover 54 engage the side walls 72, 74 of the chassis 52 to enclose the chassis when securing the cover to the chassis. The cover 54 further includes an end flange 86, similar to end flange 76 of the chassis 52, to partially enclose an end of the cover. The end flange 86 is secured to the ends of the top wall 80 and the side walls 82, 84 of the cover 54.

In one embodiment, the side walls 72, 74 of the chassis 52 include openings 90, 92 formed therein, respectively, and the side walls 82, 84 of the cover 54 include slightly larger openings 94, 96 formed therein, respectively. When the cover 54 is positioned on the chassis 52, the openings 94, 96 of the cover are aligned with the openings 90, 92 of the chassis, respectively. The openings 90, 92 of the side walls 72, 74 of the chassis 52 are sized to threadably receive the chassis mounting screws 66a, e.g., a flat head screw, to secure the cover 54 to the chassis. Although not shown, the other end of the rPDU 50 may similarly include aligned openings and chassis mounting screws to secure the opposite end of the cover 54 to the chassis 52.

Referring to FIGS. 8A and 8B, since the lower clamp portion 60 and the upper clamp portion 62 are identical in construction, the lower clamp portion 60 will be shown and described as follows. As shown, the lower clamp portion 60 includes a U-Shaped body having a flat bottom surface 100 configured to engage the bottom wall 70 of the chassis 52 or the top wall 80 of the cover 54, two side surfaces 102, 104 configured to engage respective side walls 72, 74 of the chassis and the side walls 80, 82 of the cover, and a semi-circular or arcuate top surface 106 configured to engage the power cord 56. The arcuate top surface 106 of the body of the lower clamp portion 60 includes two spaced apart grooves 108, 110 formed therein. The grooves 108, 110 are provided to break up the surface of the arcuate top surface 106 to better engage and bite into the power cord 56 when the clamp portions 60 and 62 are assembled and secured. The flexible nature of the power cord 56 occupies the spaces within the grooves 108, 110 to provide a greater securing force on the power cord.

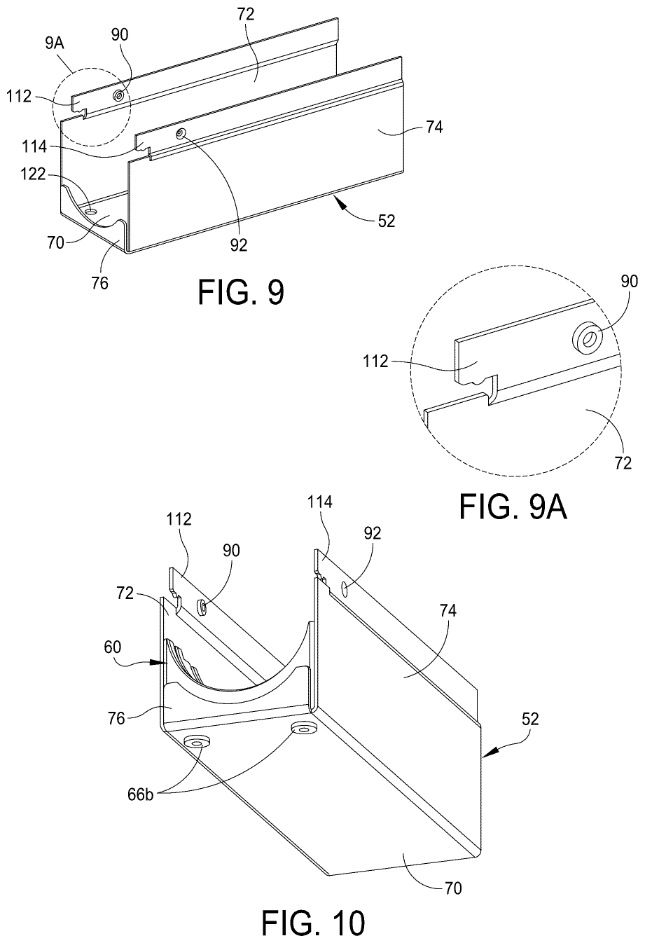

Referring back to FIGS. 6 and 7, the side walls 72, 74 of the chassis 52 include retention members 112, 114, respectively. The retention members 112, 114 are sometimes referred to as first retention members. Each retention member 112, 114 includes a protuberance formed therein. The retention members 112, 114 are positioned to engage retention members associated with the upper clamp portion 62, which as described above, is identical to the lower clamp portion 60. As shown in FIGS. 8A and 8B, the side surfaces of the clamp portion 60 include mating retention members 116, 118, respectively. The mating retention members 116, 118 are sometimes referred to as second retention members. Each mating retention member 116, 118 includes a recess configured to receive a respective protuberance of the retention members 112, 114 of the chassis 52. The retention members 112, 114 of the chassis 52 are configured to releasably engage the mating retention members 116, 118 of the clamp portion to temporarily secure the clamp portion in place when assembling the cable clamp assembly. Specifically, the protuberances of the retention members 112, 114 are received within respective recesses of the mating retention members 116, 118 with the surfaces engaging one another to prevent lateral movement of the clamp portion with respect to the chassis 52. The construction of the retention members 112, 114 of the chassis 52 are clearly shown in FIG. 9, with retention member 112 being enlarged in FIG. 9A. The opening 90 formed in the side wall 72 of the chassis 52 is shown in FIG. 9A as well.

As best shown in FIGS. 6 and 7, the lower clamp portion 60 is secured to the bottom wall 70 of the chassis 52 by the two mounting screws 66b. Specifically, the flat (bottom) surface 100 of the lower clamp portion 60 is positioned on the bottom wall 70 of the chassis 52 so that threaded openings, each indicated at 120, formed in the lower clamp portion (FIG. 8B) align with openings, each indicated at 122, formed in the bottom wall of the chassis.

As described above, the upper clamp portion 62 includes two jack screws 64, which are configured to transfer a force from the cover 54 to the upper clamp portion and the power cord 56, which is sometimes referred to as a cable, disposed between the lower clamp portion 60 and the upper clamp portion. The top wall 80 of the cover 54 includes two spaced apart openings, each indicated 124, formed therein, which, when the cover is secured to the chassis 52, are disposed over the jack screws 64. Each jack screw 64 includes a head portion having a diameter larger than a diameter of the opening 124 formed in the top wall 80 of the cover 54. Each jack screw 64 further includes a threaded end portion, with the threaded end portion of the jack screw being configured to be threadably received within a respective threaded opening 120 formed in the upper clamp portion 62. The result is that when the cable clamp assembly is fully assembled, with the cover 54 being secured to the chassis 52, a tool is inserted within the opening 124 of the cover to access the head portion of the jack screw 64. In the shown embodiment, the diameter of the opening 124 formed in the top wall 80 of the cover 54 is sized to receive a tool therein to rotate the jack screw 64. In one embodiment, when the jack screw 64 is rotated counterclockwise, the jack screw is rotated out of its threaded opening 120 of the upper clamp portion 60. Once the head portion of the jack screw 64 engages a downwardly facing surface of the top wall 80 of the cover 54, the jack screw transfers a force from the cover to the upper clamp portion 62 and the power cord 56 disposed between the lower clamp portion 60 and the upper clamp portion. It should be noted that the jack screws 64 and the threaded openings 120 may be configured to be rotated in a clockwise direction to rotate the jack screws out of their respective threaded openings.

Each of the lower clamp portion 60 and the upper clamp portion 62 further includes a vertical step cut feature 126 (FIG. 8B) associated with the mating retention member 116 or 118 on each side wall 102, 104 on the clamp portion to prevent the cable clamp assembly from sliding inward within the chassis 52 of the rPDU 50. Such a vertical step cut feature can be provided on an inner surface of each side wall of the cover as well.

FIG. 10 illustrates the end flange 76 of the chassis 52 that is configured to prevent axial movement of the lower clamp portion 60 and the power cord (not shown) from the chassis.

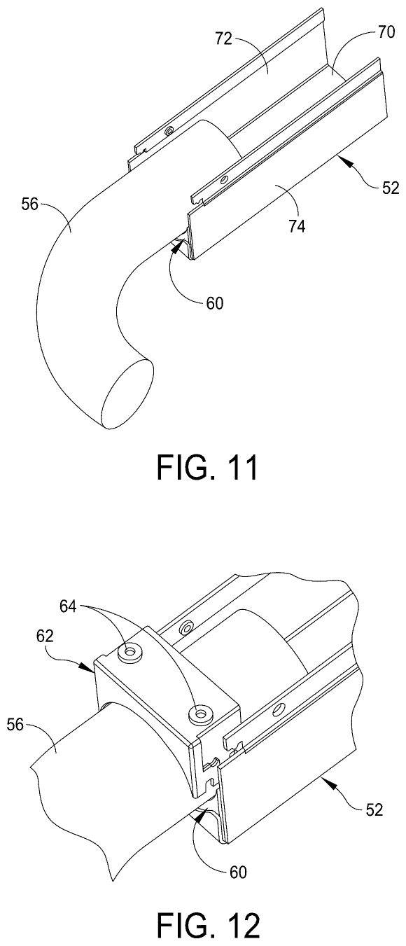

The manner in which the cable clamp assembly is assembled is described below with reference to FIGS. 11-14. In FIG. 11, the power cord 56 is placed over the lower clamp portion 60 and inserted into the end of the chassis 52. In one embodiment, several inches of the power cord 56 extend into the chassis 52 and beyond the lower clamp portion 60. In this position, the lower clamp portion 60 can be secured to the bottom wall 70 of the chassis 52 with the two mounting screws 66b.

Next, in FIG. 12, the upper clamp portion 62 is placed over the lower clamp portion 60 with the power cord 56 being disposed between the lower clamp portion and the upper clamp portion. As shown, the upper clamp portion 62 includes the two jack screws 64, which as described above are provided to secure the power cord 56 to the chassis 52 and the cover 54.

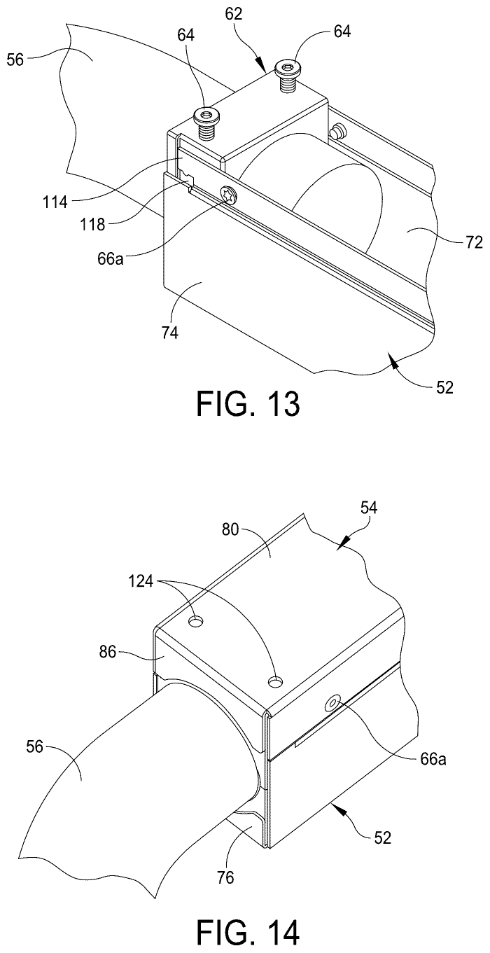

Next, in FIG. 13, the retention member 114 of the side wall 74 of the chassis 52 is positioned to engage and retain the mating retention member 118 of the upper clamp portion 62 to hold the upper clamp portion in place prior to positioning the cover 54 on the chassis.

Next, in FIG. 14, the cover 54 is positioned on the chassis 52, and the chassis mounting screws 66a are inserted into their respective openings 94, 96 of the cover and threaded openings 90, 92 of the chassis to secure the cover to the chassis.

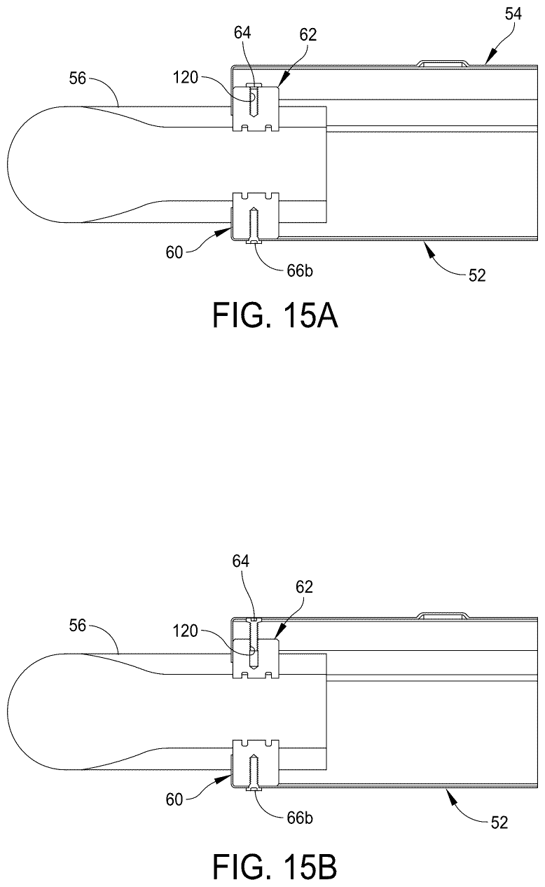

Once secured, the jack screws 64 are rotated in a counterclockwise direction to engage the cover 54 to transfer a force from the cover to the upper clamp portion 62 and the power cord 56 disposed between the lower clamp portion 60 and the upper clamp portion to secure the power cord in place. Specifically, FIG. 15A illustrates the jack screw 64 in a lowered position in which the jack screw is fully threadably received within the threaded opening 120 of the upper clamp portion 62. A tool is inserted into the opening 124 of the top wall 80 of the cover 54 to engage the head portion of the jack screw 64 to rotate the jack screw in the counterclockwise direction. FIG. 15B illustrates the jack screw 64 in a raised position in which the head portion of the jack screw engages the downwardly facing surface of the top wall 80 of the cover 54 to transfer the force from the cover to the upper clamp portion 62 and the power cord 56. Both jack screws are rotated to achieve the desired clamping force on the lower and upper clamp portions 60, 62 and the power cord 56.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A cable clamp assembly, comprising:
a chassis;
a first clamp portion coupled to the chassis;
a cover configured to releasably enclose the chassis; and
a second clamp portion configured to be positioned between the first clamp portion and the cover,
wherein the second clamp portion includes a jack screw configured to transfer a force from the cover to the second clamp portion and a cable disposed between the first clamp portion and the second clamp portion.

2. The cable clamp assembly of claim 1, wherein the chassis includes a bottom wall and two side walls extending from lateral edges of the bottom wall, the cover being configured to engage the side walls to enclose the chassis.

3. The cable clamp assembly of claim 2, wherein the first clamp portion is positioned on the bottom wall at an end of the bottom wall and the second clamp portion is positioned on the cover at an end of the cover.

4. The cable clamp assembly of claim 2, wherein the cover is secured at least one side wall of the chassis by at least one screw fastener.

5. The cable clamp assembly of claim 1, wherein the cover includes an opening formed therein over the jack screw, the jack screw including a head portion having a diameter larger than a diameter of the opening.

6. The cable clamp assembly of claim 5, wherein the diameter of the opening is sized to receive a tool therein to rotate the jack screw.

7. The cable clamp assembly of claim 5, wherein the jack screw further includes a threaded end portion, the threaded end portion of the jack screw being configured to be threadably received within a threaded opening formed in the upper clamp portion.

8. The cable clamp assembly of claim 1, wherein each of the first clamp portion and the second clamp portion includes at least one groove formed therein.

9. The cable clamp assembly of claim 1, wherein the chassis includes an end flange configured to engage the first clamp portion to prevent axial movement of the first clamp portion and the cable from the chassis.

10. The cable clamp assembly of claim 1, wherein the chassis includes a first retention member configured to releasably engage a second retention member of the second clamp portion to temporarily secure the second clamp portion in place when assembling the cable clamp assembly.

11. The cable clamp assembly of claim 1, wherein the second clamp portion includes two jack screws that are spaced apart from one another, the two jack screws being configured to transfer a force from the cover to the second clamp portion and the cable disposed between the first clamp portion and the second clamp portion.

12. The cable clamp assembly of claim 1, wherein the first clamp portion and at least one screw fastener are configured to secure the first clamp portion to the chassis.

13. A method of assembling a cable clamp assembly, the method comprising:
positioning a first clamp portion and a cable in a chassis;
positioning a second clamp portion over the cable and on the first clamp portion;
positioning a cover on the chassis to enclose the first clamp portion and the second clamp portion;
securing the cover to the chassis; and
rotating a jack screw configured to transfer a force from the cover to the second clamp portion and a cable disposed between the first clamp portion and the second clamp portion to secure the cable in place.

14. The method of claim 13, wherein positioning the second clamp portion on the cable over the first clamp portion includes retaining the second clamp portion to the chassis.

15. The method of claim 14, wherein retaining the second clamp portion to the chassis is achieved by a first retention member of the chassis that is configured to releasably engage a second retention member of the second clamp portion to temporarily secure the second clamp portion in place.

16. The method of claim 13, wherein the first clamp portion is positioned on the bottom wall at an end of the bottom wall and the second clamp portion is positioned on the cover at an end of the cover.

17. The method of claim 13, wherein the cover includes an opening formed therein over the jack screw, the jack screw including a head portion having a diameter larger than a diameter of the opening.

18. The method of claim 17, wherein the jack screw further includes a threaded end portion, the threaded end portion of the jack screw being configured to be threadably received within a threaded opening formed in the upper clamp portion.

19. The method of claim 13, further comprising preventing axial movement of the first clamp portion and the cable from the chassis.

20. The method of claim 13, further comprising securing the first clamp portion to the chassis by at least one screw fastener.
